(19) United States
(12) Patent Application Publication
(10) Pub. No.: US 2015/0213898 A1
(43) Pub. Date: Jul. 30, 2015

(54) Byte Erasable Non-volatile Memory Architecture And Method Of Erasing Same

(71) Applicant: Silicon Storage Technololgy, Inc., San Jose, CA (US)

(72) Inventor: Nhan Do, Saratoga, CA (US)

(73) Assignee: Silicon Storage Technololgy, Inc., San Jose, CA (US)

(21) Appl. No.: 14/165,348

(22) Filed: Jan. 27, 2014

(51) Int. Cl. G11C 16/14; G11C 16/04; H01L 27/115; G11C 5/06

(52) U.S. Cl. CPC G11C 16/14; G11C 5/063; G11C 16/0408; H01L 27/11519; H01L 27/11521

(57) ABSTRACT

Memory cells arranged in rows and columns, each with source and drain regions of equal breakdown voltages, and floating and control gates over the channel region. The memory cell rows are arranged in clusters each with a source line connecting all the source regions in just that cluster. Word lines each connect all the control gates for a row of memory cells. Bit lines each connect all the drain regions for a column of memory cells. Source line interconnects each connect all the source lines for a column of clusters. One cluster is erased by applying a positive voltage to a word line for that cluster and ground potential to other word lines, ground potential to the source line interconnect for that cluster and a positive voltage to other source line interconnects, and ground potential to the bit lines for that cluster and a positive voltage to other bit lines.

### FIELD OF THE INVENTION

The present invention relates to non-volatile memory devices, and more particularly to memory cell and array architecture, and method of operation, that enhances the granularity of memory cell erasure.

### BACKGROUND OF THE INVENTION

Non-volatile semiconductor memory devices are well-known in the art. See, for example, U.S. Pat. No. 5,029,130, which is incorporated herein by reference for all purposes. Referring to FIG. 1, there is shown a conventional non-volatile semiconductor memory cell 10. The cell 10 comprises semiconductor substrate 12, such as silicon. The substrate 12, in one embodiment, can be a P-type silicon substrate.

Within the substrate 12 are defined source region 14 and drain region 16 with a channel region 18 therebetween. The source region 14 is formed using a double implant process as compared to a single implant process for the drain region 16, such that the source region 14 has a high breakdown voltage (e.g. ˜11.5 volts or greater) compared to the low breakdown voltage of the drain region 16 (e.g. ˜5 volts or less). Disposed over the source region 16, channel region 18, and drain region 14 is a first layer 20 of insulating material. The first layer 20 can be an insulating material made from silicon dioxide, silicon nitride or silicon oxynitride. Disposed over the first layer 20 is a floating gate 22. The floating gate 22 is positioned over a first portion of the channel region 18 and over a portion of the source region 16. The floating gate 22 can be a polysilicon gate and in one embodiment is a re-crystallized polysilicon gate. A second insulating layer 24 is formed over the floating gate 22 and a third insulating layer 26 disposed laterally adjacent to the floating gate 22. These insulating layers can be silicon dioxide, silicon nitride or silicon oxynitride. A control gate 28 (word line) has two portions: a first portion 28a is disposed laterally adjacent to the floating gate and over a second portion of the channel region 18, and a second portion 28b that extends up and over a portion of the floating gate 22. The first portion 28a can, but need not, also partially overlap the drain region 16.

Initially, when it is desired to erase cell 10, a ground potential is applied to the source 14 and drain 16. A high-positive voltage is applied to the control gate 28. Charges on the floating gate 22 are induced through the Fowler-Nordheim tunneling mechanism to tunnel through the third layer 26 to the control gate 28, leaving the floating gate 22 positively charged.

When a selected cell 10 is desired to be programmed, a ground or small potential is applied to the drain region 16. A positive voltage in the vicinity of the threshold voltage of the MOS structure defined by the control gate 28 is applied to the control gate 28. A positive high voltage is applied to the source region 14. Electrons generated by the drain region 16 will flow from the drain region 16 towards the source region 14 through a weakly-inverted channel region 18. When the electrons reach the region where insulating layer 26 separates the control gate 28 and floating gate 22, the electrons see a steep potential drop approximately equal to the source voltage. The electrons will accelerate and become heated and some of them will be injected into and through the first insulating layer 20 onto the floating gate 22. The injection of electrons onto the floating gate 22 will continue until the charged floating gate 22 can no longer sustain a high surface potential beneath, to generate hot electrons. At that point, the electrons or the negative charges in the floating gate 22 will “turn off” the electrons from flowing from the drain region 16 onto the floating gate 22.

Finally, in a read cycle, ground potential is applied to the source region 14. Conventional transistor read voltages are applied to the drain region 16 and to the control gate 28, respectively. If the floating gate 22 is positively charged (i.e., the floating gate is discharged), then the channel region 18 directly beneath the floating gate 22 is turned on. When the control gate 28 is raised to the read potential, the region of the channel region 18 directly beneath the first portion 28a is also turned on. Thus, the entire channel region 18 will be turned on, causing electrical current to flow between the drain region 16 to the source region 14. This would be the “1” state.

On the other hand, if the floating gate 22 is negatively charged, the channel region 18 directly beneath the floating gate 22 is either weakly turned on or is entirely shut off. Even when the control gate 28 is raised to the read potential, little or no current will flow through the portion of the channel region 18 directly beneath the floating gate 22. In this case, either the current is very small compared to that of the “1” state or there is no current at all. In this manner, the cell 10 is sensed to be programmed at the “0” state.

It is known to configure the memory cell 10 of FIG. 1 as an array 30 of pairs of mirror sets of such memory cells, with each memory cell pair sharing a single common source region 14, as illustrated in FIG. 2. Each source region 14 is formed as a continuous source line extending in the row direction such that it is shared among all the memory cell pairs in that row of memory cell pairs. Each control gate 14 is formed as a continuous word line extending in the row direction such that it is shared among all the memory cells 10 in that row of memory cells. The source lines 14 from each row of memory cell pairs can be, but need not be, connected together as shown in FIG. 2. The drain regions 16 for each column of memory cells are connected together as continuous bit lines (i.e. each bit line is electrically connected to all the drain regions 16 for the memory cells in that column). The array also includes peripheral circuitry (not shown) that includes conventional row address decoding circuitry, column address decoding circuitry, sense amplifier circuitry, output buffer circuitry and input buffer circuitry. These conventional circuits are well known in the art.

In this array configuration, a target memory cell can be erased, programmed and read by applying the following voltages in Table 1 (where selected lines contain the target memory cell, and the unselected lines do not).

TABLE 1

| | Word Line (28) | | Source Line (14) | | Bit Line (16) | |
|---|---|---|---|---|---|---|
| | Voltage | | Voltage | | Voltage | |
| | Selected | Unselected | Selected | Unselected | Selected | Unselected |
| Erase | 11.5 | 0 | 0 | 0 | 0 | 0 |
| Program | 1.5 | 0 | 9.5 | 0 | 1 | Vdd |
| Read | 2.5 | 0 | 0 | 0 | 0.8 | 0 |

With the above configuration, individual memory cells 10 can be programmed and read. However, the memory cells 10 cannot be individually erased. Rather, an entire row of memory cells is erased in a single erase operation. If just one memory cell, or a byte of data (i.e. 8 memory cells) needed to be erased, all the other bytes of data stored in the same row of memory cells would be erased as well, and would need to be programmed back into the array after the erase operation.

This same issue arises for memory cells having one or more additional gates. See, for example, U.S. Pat. No. 7,315,056, which is incorporated herein by reference for all purposes. Referring to FIG. 3, there is shown a conventional non-volatile memory cell 110, which has the same corresponding structure as the memory cell 10 (substrate 112, source region 114, drain region 116, channel region 118, first insulating layer 120, floating gate 122, second insulating layer 124, third insulating layer 126 and control gate 128 with lower and upper portion 128a and 128b). Additionally, a coupling gate 132 is formed with a lower portion 132a disposed over and insulated from source region 114, and an upper portion 132b that extends up and over the floating gate 122.

FIG. 4 illustrates a conventional array 130 of the memory cells 110, which essentially has the same configuration as array 30 except for the addition of coupling gates 132 formed as a continuous coupling gate line extending in the row direction such that it is shared among all the memory cell pairs in that row of memory cell pairs. In this array configuration, a target memory cell can be erased, programmed and read by applying the following voltages in Table 2 (where selected lines contain the target memory cell, and the unselected lines do not).

TABLE 2

| | Word Line | | Source Line | | Bit Line | | Coupling Gate Line | |
|---|---|---|---|---|---|---|---|---|
| | (128) Voltage | | (114) Voltage | | (116) Voltage | | (132) Voltage | |
| | Selected | Unsel. | Selected | Unsel. | Selected | Unsel. | Selected | Unsel. |
| Erase | 11.5 | 0 | 0 | 0 | 0 | 0 | 0 | 0 |
| Program | 1.5 | 0 | 9.5 | 0 | 1 | Vdd | 0-5 | 0 |
| Read | 2.5 | 0 | 0 | 0 | 0.8 | 0 | 3-5 | 0 |

With the above configuration, individual memory cells 110 can be programmed and read. However, the memory cells 110 cannot be individually erased. Rather, an entire row of memory cells is erased in a single erase operation. If just one memory cell, or a byte of data (i.e. 8 memory cells) needed to be erased, all the other bytes of data stored in the same row of memory cells would be erased as well, and would need to be programmed back into the array after the erase operation.

There is a need for an array architecture that allows for just a portion of the memory cells in each row of memory cells (e.g. 8 memory cells storing a byte of data) to be erased without disturbing the programming state of other memory cells (especially the other memory cells in the same row of memory cells).

### BRIEF SUMMARY OF THE INVENTION

The aforementioned problems and needs are addressed by a memory device that includes a plurality of memory cells arranged in rows and columns. Each memory cell includes spaced apart source and drain regions in a semiconductor substrate with a channel region extending therebetween, wherein the source region and the drain region form junctions with substantially equal breakdown voltages, a floating gate disposed over and insulated from a first portion of the channel region, and a control gate disposed over and insulated from a second portion of the channel region. Each row of the memory cells are arranged in clusters of the memory cells with the clusters arranged in rows and columns, wherein each cluster comprises a source line connecting together the source regions of the memory cells in the cluster, and wherein each source line is not connected to the source regions of memory cells in other clusters in a same row of clusters. Each row of the memory cells comprises a word line connecting together all the control gates of the memory cells in the row of memory cells. Each column of the memory cells comprises a bit line connecting together all the drain regions of the memory cells in the column of memory cells. Each column of clusters comprises a source line interconnect connecting together all the source lines of the clusters in the column of clusters.

A method of erasing a portion of an array of memory cells which are arranged in rows and columns. Each of the memory cells includes spaced apart source and drain regions in a semiconductor substrate with a channel region extending therebetween, wherein the source region and the drain region form junctions with substantially equal breakdown voltages, a floating gate disposed over and insulated from a first portion of the channel region, and a control gate disposed over and insulated from a second portion of the channel region. Each row of the memory cells are arranged in clusters of the memory cells with the clusters arranged in rows and columns, wherein each cluster comprises a source line connecting together the source regions of the memory cells in the cluster, wherein each source line is not connected to the source regions of memory cells in other clusters in a same row of clusters. Each row of the memory cells comprises a word line connecting together all the control gates of the memory cells in the row of memory cells. Each column of the memory cells comprises a bit line connecting together all the drain regions of the memory cells in the column of memory cells. Each column of clusters comprises a source line interconnect connecting together all the source lines of the clusters in the column of clusters. The method of erasing memory cells in one of the clusters includes applying a positive voltage to one of the word lines for the one cluster and ground potential to the others of the word lines, applying a ground potential to the source line interconnect for the one cluster and a positive voltage to the others of the source line interconnects, and applying a ground potential to the bit lines for the one cluster and a positive voltage to the others of the bit lines, wherein electrons on the floating gates of the memory cells in the one cluster tunnel from the floating gates to the control gates.

Other objects and features of the present invention will become apparent by a review of the specification, claims and appended figures.

### BRIEF DESCRIPTION OF THE DRAWINGS

FIG. 1 is a cross sectional view of a conventional non-volatile memory cell.

FIG. 2 is a top view of a conventional array architecture for the memory cell of FIG. 1.

FIG. 3 is a cross sectional view of an alternate conventional non-volatile memory cell.

FIG. 4 is a top view of a conventional array architecture for the memory cell of FIG. 3.

FIG. 5 is a cross sectional view of a non-volatile memory cell of the present invention.

FIG. 6 is a top view of an array architecture for the memory cell of FIG. 5.

FIG. 7 is a cross sectional view of an alternate embodiment of the non-volatile memory cell of the present invention.

FIG. 8 is a top view of an array architecture for the memory cell of FIG. 7.

### DETAILED DESCRIPTION OF THE INVENTION

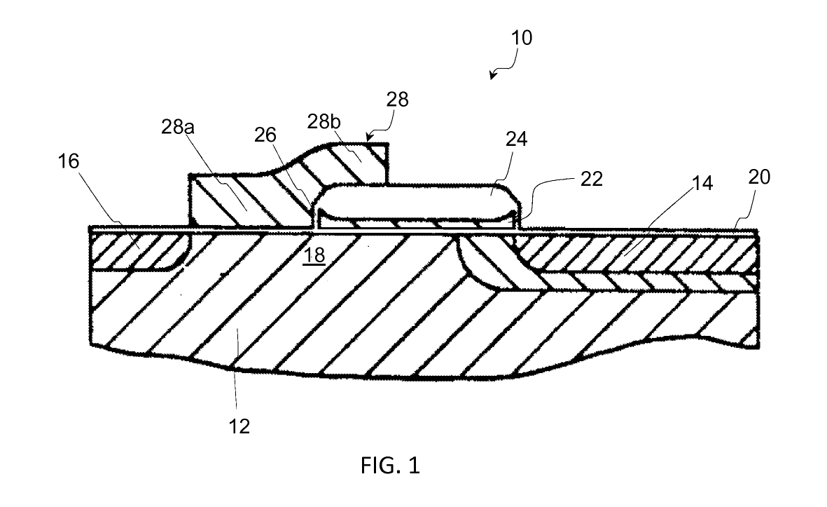

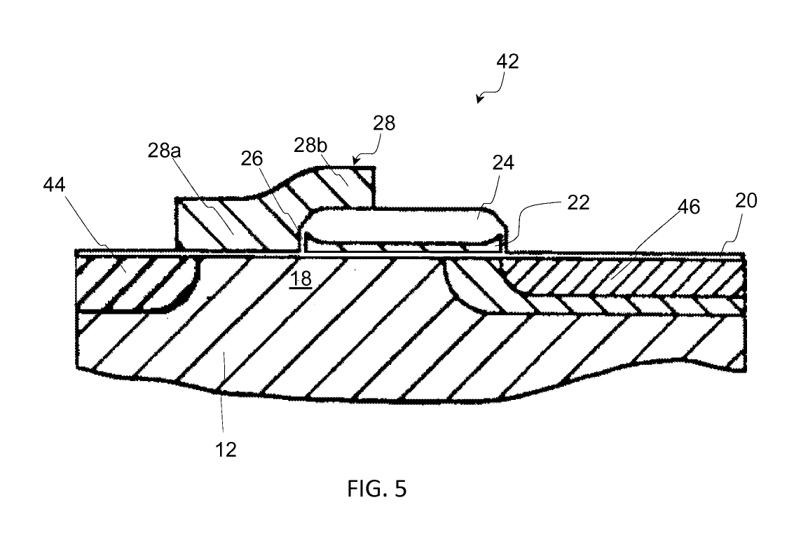

The present invention is a memory cell and array architecture, of an array 40 of memory cells 42, that allows for just some of the memory cells in each row (e.g. just 8 of the memory cells) to be erased in an erase operation, without disturbing the programming state of other memory cells in that row or in other rows. The memory cell 42 is illustrated in FIG. 5, and includes similar structure denoted by the same element numbers as memory cell 10 of FIG. 1. Memory cell 42 differs from memory cell 10 in that drain region 44 is also a high voltage junction as is source region 46. Thus, both source region 46 and drain region 44 are high voltage junctions having a high breakdown voltage (˜11.5 volts or greater).

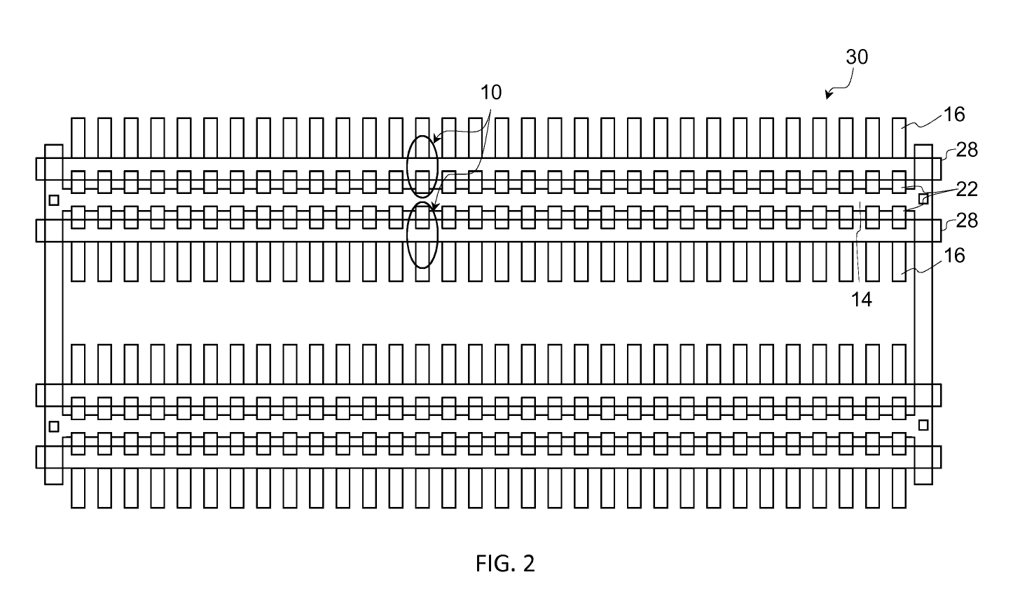

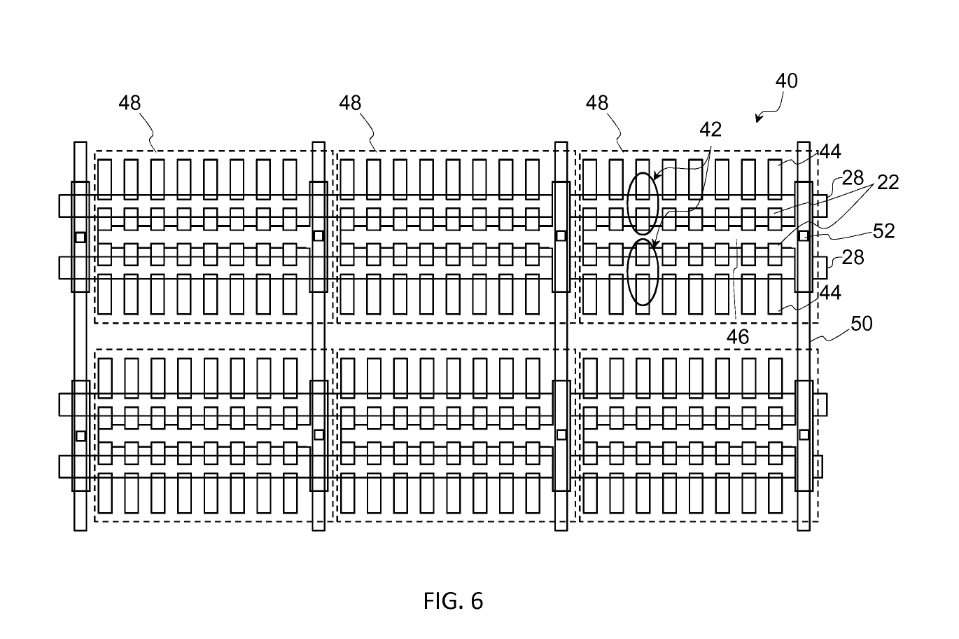

The architecture of the array 40 of memory cells 42 is shown in FIG. 6, and includes similar structure denoted by the same element numbers as the array 30 of FIG. 2. Array 40 differs from array 30 (in addition to the differences in memory cell 42 disclosed above) in that the source regions 46 are formed as a continuous source line extending in the row direction only for a small group of memory cell pairs (e.g. for a cluster 48 of memory cell pairs). Therefore, the array 40 includes a plurality rows and columns of memory cell clusters 48, each with its own shared source line 46. Each word line 28 extends in the row direction and is shared among the row memory cells 42 for a plurality of the clusters 48. The array 40 further includes source line interconnects 50, each of which extends vertically and is electrically connected to all the source lines 46 (via vertical interconnects 52) for one column of the clusters 48. Therefore, applying a voltage to any given source line interconnect 50 effectively applies that voltage to all the source lines 46 for that column of clusters 48.

For the non-limiting exemplary embodiment illustrated in FIG. 6, each cluster 48 includes eight pairs of memory cells 42. For each cluster 48, the upper row of eight memory cells 42 stores one byte of data (e.g. eight bits of data, one for each memory cell 42) and the lower row of eight memory cells 42 stores another byte of data.

For memory cell array 40, a target memory cell 42 can be programmed and read by applying the same voltages as disclosed in Table 1 above with respect to memory cell array 30. However, a single sub-row of memory cells 42 (i.e. a single row of memory cells 42 in a single cluster 48) can be erased in array 40 without affecting the programming state of other memory cells 42 (even memory cells 42 in the same row as the target sub-row but in different clusters 48). Sub-row erase is achieved by applying the voltages in the Table 3 below (where the selected lines contain or contact the target sub-row of memory cells 42, and the unselected lines do not):

TABLE 3

| | Word Line (28) Voltage | | Source Line (46/50) Voltage | | Bit Line (44) Voltage | |
|---|---|---|---|---|---|---|
| | Selected | Unselected | Selected | Unselected | Selected | Unselected |
| Erase | 11.5 | 0 | 0 | 10-13 | 0 | 10-13 |

For each of the memory cells 42 in the target sub-row, they include the selected word line, selected source line and selected bit line. Therefore, ground potential is supplied to both the source region 46 and drain region 44, and a high positive voltage is applied to the control gate 28, where charges on the floating gate 22 are induced through the Fowler-Nordheim tunneling mechanism to tunnel through the third layer 26 to the control gate 28, leaving the floating gate 22 positively charged.

For each of the other memory cells 42 in the same row as the target sub-row (i.e. same row of memory cells but in different clusters 48), they include selected word line, unselected source line and unselected bit line. Therefore, high positive voltages are applied to the control gate 28, source region 46 and drain region 44. With high voltages coupled to both ends of the floating gate 22, the electrons do not tunnel off the floating gate 22 thus preserving its program state.

For each of the memory cells 42 in a different row but in the same cluster 48 as the target sub-row, they include the unselected word line, selected source line and selected bit lines. Therefore, ground potential is applied to the source region 46, drain region 44, and control gate 28. Thus, the programming state of these memory cells is preserved.

For each of the memory cells 42 in a different row and a different column as the target sub-row, they include unselected word lines, unselected source lines and unselected bit lines. Therefore, high positive voltages are applied to both the source region 46 and drain region 44, and a ground potential is applied to the control gate 28. With high voltages coupled to both ends of the floating gate 22, the electrons do not tunnel off the floating gate 22 thus preserving its program state.

For each of the memory cells 42 in a different row and different cluster 48, but the same column, as the target sub-row (i.e. same column of clusters 48 as the cluster 48 containing the target sub-row), they include unselected word lines, selected source lines (due to source line interconnects 50), and selected bit lines. Therefore, ground potential is applied to the source region 46, drain region 44, and control gate 28. Thus, the programming state of these memory cells is preserved.

In the exemplary embodiment described above, with each sub-row containing 8 memory cells, individual bytes of the data can be erased separately (i.e. one at a time), without disturbing the stored state of other stored bytes of data.

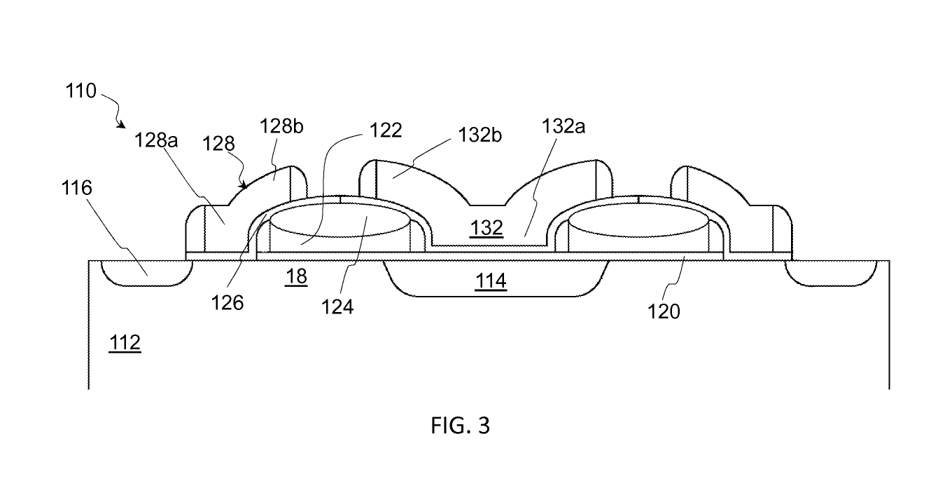

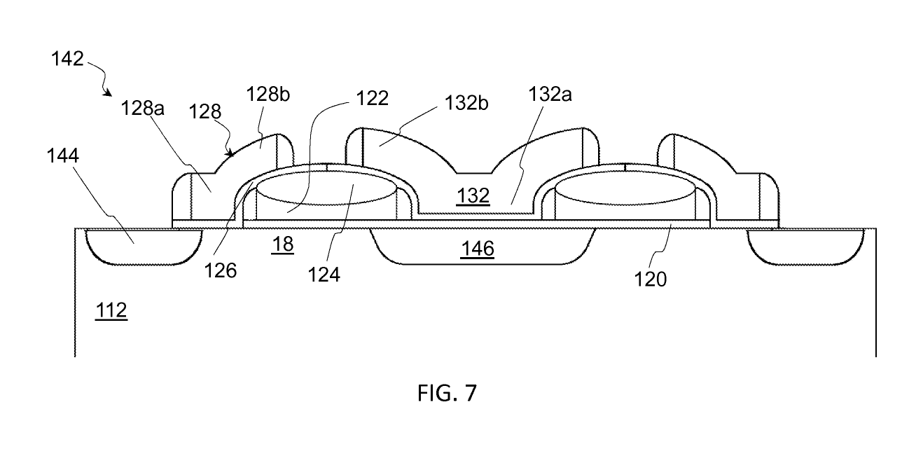

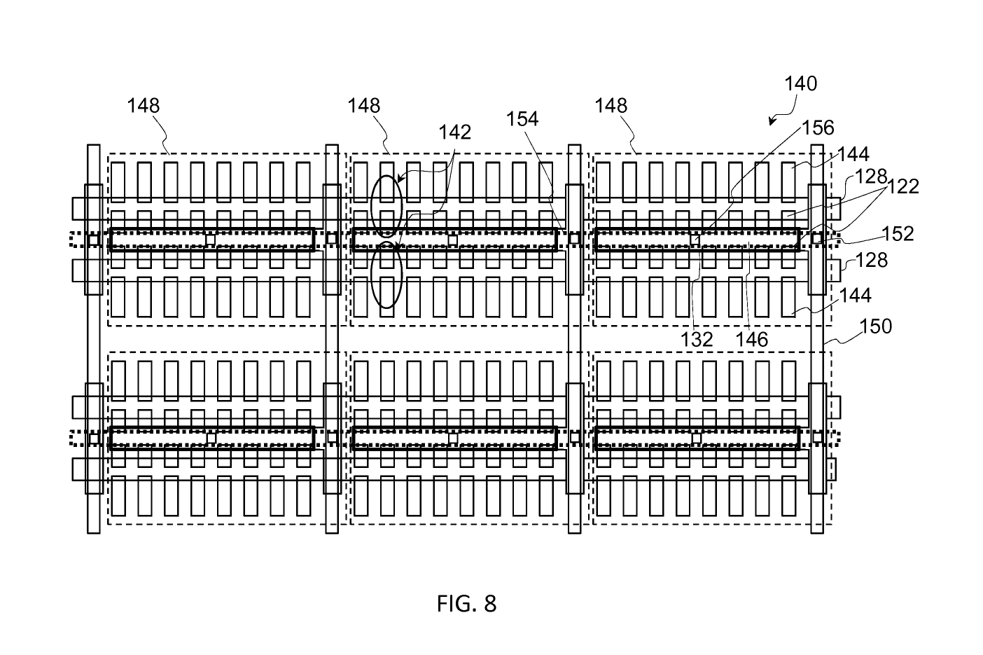

FIGS. 7-8 illustrate an alternate embodiment for memory cells that include a third gate (e.g. a coupling gate). Specifically, FIG. 7 illustrates memory cell 142, which includes similar structure denoted by the same element numbers as memory cell 110 of FIG. 3. Memory cell 142 differs from memory cell 110 in that drain region 144 is also a high voltage junction as is source region 146. Thus, both source region 146 and drain region 144 have the same high breakdown voltage (˜11.5 volts or greater).

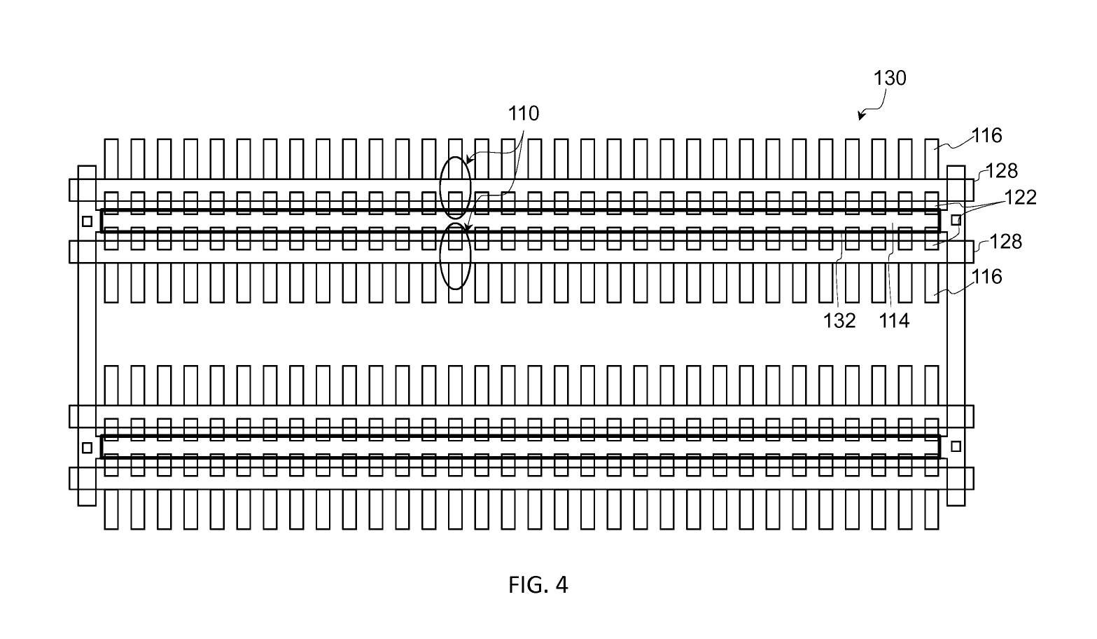

The architecture of the array 140 of memory cells 142 is shown in FIG. 8, and includes similar structure denoted by the same element numbers as the array 130 of FIG. 4. Array 140 differs from array 130 (in addition to the differences in memory cell 142 disclosed above) in that the source regions 146 are formed as a continuous source line extending in the row direction only for a small group of memory cell pairs (e.g. for a cluster 148 of memory cell pairs). Therefore, the array 140 includes a plurality rows and columns of memory cell clusters 148, each with its own shared source line 146. Each word line 128 extends in the row direction and is shared among the row memory cells 142 for a plurality of the clusters 148. The array 140 further includes source line interconnects 150, each of which extends vertically and is electrically connected to all the source lines 146 (via vertical interconnects 152) for one column of the clusters 148. Therefore, applying a voltage to any given source line interconnect 150 effectively applies that voltage to all the source lines 146 for that column of clusters 148. The coupling gates 132 are formed as a continuous coupling gate line extending in the row direction only for the memory cells in that cluster 148. The array 140 further includes coupling gate line interconnects 154, each of which extends horizontally (in the row direction) and is electrically connected to all the coupling gate lines 132 (via vertical interconnects 156) for that row of memory cells 142. Therefore, applying a voltage to any given control gate line interconnect 154 effectively applies that voltage to all the control gate lines 132 for that row of memory cells 142.

For the non-limiting exemplary embodiment illustrated in FIG. 8, each cluster 148 includes eight pairs of memory cells 142. For each cluster 148, the upper row of eight memory cells 142 stores one byte of data (e.g. eight bits of data, one for each memory cell 142) and the lower row of eight memory cells 142 stores another byte of data.

For memory cell array 140, a target memory cell 142 can be programmed and read by applying the same voltages as disclosed in Table 2 above with respect to memory cell array 130. However, a single sub-row of memory cells 142 (i.e. a single row of memory cells 142 in a single cluster 148) can be erased in array 140 without affecting the programming state of other memory cells 142 (even memory cells 142 in the same row as the target sub-row but in different clusters 148). Sub-row erase is achieved by applying the voltages in the Table 4 below (where the selected lines contain or contact the target sub-row of memory cells 142, and the unselected lines do not):

TABLE 4

| | Word Line | | Source Line | | Bit Line | | Coupling Gate Line | |
|---|---|---|---|---|---|---|---|---|
| | (128) Voltage | | (146/150) Voltage | | (144) Voltage | | (132/154) Voltage | |
| | Selected | Unsel. | Selected | Unsel. | Selected | Unsel. | Selected | Unsel. |
| Erase | 11.5 | 0 | 0 | 10-13 | 0 | 10-13 | 0 | 0 |

The theory of operation for array 140 is substantially the same as that stated above for array 40.

It is to be understood that the present invention is not limited to the embodiment(s) described above and illustrated herein, but encompasses any and all variations falling within the scope of the appended claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Lastly, single layers of material could be formed as multiple layers of such or similar materials, and vice versa.

It should be noted that, as used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements therebetween.

What is claimed is:

1. A memory device, comprising:
a plurality of memory cells arranged in rows and columns, wherein each of the memory cells comprises:
spaced apart source and drain regions in a semiconductor substrate with a channel region extending therebetween, wherein the source region and the drain region form junctions with substantially equal breakdown voltages;
a floating gate disposed over and insulated from a first portion of the channel region; and
a control gate disposed over and insulated from a second portion of the channel region;
each row of the memory cells are arranged in clusters of the memory cells with the clusters arranged in rows and columns, wherein each cluster comprises a source line connecting together the source regions of the memory cells in the cluster, wherein each source line is not connected to the source regions of memory cells in other clusters in a same row of clusters;
each row of the memory cells comprises a word line connecting together all the control gates of the memory cells in the row of memory cells;
each column of the memory cells comprises a bit line connecting together all the drain regions of the memory cells in the column of memory cells;
each column of clusters comprises a source line interconnect connecting together all the source lines of the clusters in the column of clusters.

2. The memory device of claim 1, wherein for each of the memory cells, the control gate includes a first portion disposed over and insulated from the second portion of the channel region, and a second portion that extends over and is insulated from the floating gate.

3. The memory device of claim 1, wherein the memory cells are arranged as pairs of the memory cells with each pair in two of the rows of the memory cells, wherein the source regions for each of the memory cell pairs are formed as a continuous region.

4. The memory device of claim 3, wherein each of the clusters includes eight of the memory cells in one of the rows of the memory cells and eight of the memory cells in another of the rows of the memory cells.

5. The memory device of claim 1, wherein each of the memory cells further comprises a coupling gate disposed over and insulated from the source region.

6. The memory device of claim 5, wherein each of the clusters of the memory cells further comprises a coupling gate line connecting together the coupling gates of the memory cells in the cluster, wherein each coupling gate line is not connected to the coupling gates of memory cells in other clusters in the same row of clusters.

7. The memory device of claim 1, wherein the source region junction and drain region junction each have a breakdown voltage of substantially 11.5 volts or greater.

8. A method of erasing a portion of an array of memory cells arranged in rows and columns, wherein each of the memory cells comprises:
spaced apart source and drain regions in a semiconductor substrate with a channel region extending therebetween, wherein the source region and the drain region form junctions with substantially equal breakdown voltages,
a floating gate disposed over and insulated from a first portion of the channel region, and
a control gate disposed over and insulated from a second portion of the channel region;
wherein:
each row of the memory cells are arranged in clusters of the memory cells with the clusters arranged in rows and columns, wherein each cluster comprises a source line connecting together the source regions of the memory cells in the cluster, wherein each source line is not connected to the source regions of memory cells in other clusters in a same row of clusters,
each row of the memory cells comprises a word line connecting together all the control gates of the memory cells in the row of memory cells,
each column of the memory cells comprises a bit line connecting together all the drain regions of the memory cells in the column of memory cells,
each column of clusters comprises a source line interconnect connecting together all the source lines of the clusters in the column of clusters;
the method of erasing memory cells in one of the clusters, comprising:
applying a positive voltage to one of the word lines for the one cluster and ground potential to the others of the word lines,
applying a ground potential to the source line interconnect for the one cluster and a positive voltage to the others of the source line interconnects, and
applying a ground potential to the bit lines for the one cluster and a positive voltage to the others of the bit lines;
wherein electrons on the floating gates of the memory cells in the one cluster tunnel from the floating gates to the control gates.

9. The method of claim 8, wherein the positive voltage applied to the one word line is substantially 11.5 volts.

10. The method of claim 9, wherein the positive voltage applied to the others of the source line interconnects is substantially 10-13 volts, and the positive voltage applied to the others of the bits lines is substantially 10-13 volts.

11. The method of claim 8, wherein the source region junction and drain region junction each have a breakdown voltage of substantially 11.5 volts or greater.

12. The method of claim 8, wherein for each of the memory cells, the control gate includes a first portion disposed over and insulated from the second portion of the channel region, and a second portion that extends over and is insulated from the floating gate.

13. The method of claim 8, wherein the memory cells are arranged as pairs of the memory cells with each pair in two of the rows of the memory cells, wherein the source regions for each of the memory cell pairs are formed as a continuous region.

14. The method of claim 13, wherein each of the clusters includes eight of the memory cells in one of the rows of the memory cells and eight of the memory cells in another of the rows of the memory cells.

15. The method of claim 8, wherein each of the memory cells further comprises a coupling gate disposed over and insulated from the source region, and wherein each of the clusters of the memory cells further comprises a coupling gate line connecting together the coupling gates of the memory cells in the cluster, wherein each coupling gate line is not connected to the coupling gates of memory cells in other clusters in the same row of clusters, the method further comprising:
applying a positive voltage to the coupling gate lines.

16. The method of claim 10, wherein each of the memory cells further comprises a coupling gate disposed over and insulated from the source region, and wherein each of the clusters of the memory cells further comprises a coupling gate line connecting together the coupling gates of the memory cells in the cluster, wherein each coupling gate line is not connected to the coupling gates of memory cells in other clusters in the same row of clusters, the method further comprising:
applying a ground potential to the coupling gate lines.
